(19) United States
(12) Patent Application Publication
(10) Pub. No.: US 2024/0412350 A1
(43) Pub. Date: Dec. 12, 2024

(54) OPTICAL METROLOGY DEVICE

(71) Applicant: Samsung Electronics Co., Ltd., Suwon-si (KR)

(72) Inventors: Minsu Jo, Suwon-si (KR); Hankyoul Moon, Suwon-si (KR); Gawoon Bang, Suwon-si (KR); Woohyeon So, Suwon-si (KR); Jongsun An, Suwon-si (KR); Jooyoun Kang, Suwon-si (KR); Kwangsoo Kim, Suwon-si (KR); Karam Lee, Suwon-si (KR); Kwangsung Lee, Suwon-si (KR); Sewon Jeon, Suwon-si (KR)

(21) Appl. No.: 18/406,546

(22) Filed: Jan. 8, 2024

(30) Foreign Application Priority Data
Jun. 7, 2023 (KR) 10-2023-0073065

(51) Int. Cl. G06T 7/00; G06T 5/50; G06T 5/60; G06T 5/80; G06T 7/586; G06V 10/143; G06V 10/60; G06V 10/77; G06V 10/82

(52) U.S. Cl. CPC G06T 7/001; G06T 5/50; G06T 5/60; G06T 5/80; G06T 7/586; G06V 10/143; G06V 10/60; G06V 10/7715; G06V 10/82; G06T 2207/10152; G06T 2207/20081; G06T 2207/20084; G06T 2207/30148

(57) ABSTRACT

An optical metrology device includes a lighting unit configured to simultaneously illuminate first illumination light at a first angle of incidence having a difference more than a critical angle from a measurement angle, and second illumination light having a wavelength, different from a wavelength of the first illumination light, at a second angle of incidence having a difference of equal to or less than the critical angle from the measurement angle, onto a surface of a substrate; an optical system configured to collect reflected light from the surface of the substrate according to the first illumination light and the second illumination light; and a multichannel camera configured to generate an original image in which a dark field image and a bright field image of the surface of the substrate are integrated, based on the reflected light collected by the optical system.

### CROSS-REFERENCE TO RELATED APPLICATION(S)

This application claims benefit of priority to Korean Patent Application No. 10-2023-0073065, filed on Jun. 7, 2023 in the Korean Intellectual Property Office, the disclosure of which is incorporated herein by reference in its entirety.

### BACKGROUND

The present inventive concept relates to an optical metrology device for performing an optical measurement on a substrate, a substrate processing device including the optical metrology device, and an optical inspection method for the substrate.

As a degree of integration of a semiconductor device increases, a defect such as a scratch, discoloration, or the like, becomes a critical factor influencing electrical characteristics and performance of the semiconductor device.

An optical inspection may be performed on a semiconductor substrate to detect the defect in or on the semiconductor device. The optical inspection may include a bright field inspection using bright field illumination and a dark field inspection using dark field illumination. The bright field inspection may effectively detect discoloration, but it may be difficult to detect a scratch, and the dark field inspection may effectively detect a scratch, but may be difficult to detect discoloration.

When the bright field inspection and the dark field inspection are performed on the semiconductor device, various types of defects such as discoloration and a scratch may be effectively detected. However, when the optical inspection needs to be carried out by sequentially performing the bright field illumination and the dark field illumination, a time period required to inspect the substrate may increase.

### SUMMARY

An aspect of the present inventive concept is to provide an optical metrology device, a substrate processing device, and an optical inspection method, which are capable of effectively detecting various types of defects while reducing a time period required for inspecting a defect of a substrate.

According to an aspect of the present inventive concept, an optical metrology device includes a lighting unit configured to simultaneously illuminate first illumination light at a first angle of incidence having a difference more than a critical angle from a measurement angle, and second illumination light having a wavelength, different from a wavelength of the first illumination light, at a second angle of incidence having a difference of equal to or less than the critical angle from the measurement angle, onto a surface of a substrate; an optical system configured to collect reflected light from the surface of the substrate according to the first illumination light and the second illumination light; and a multichannel camera configured to generate an original image in which a dark field image and a bright field image of the surface of the substrate are integrated, based on the reflected light collected by the optical system.

According to an aspect of the present inventive concept, an optical metrology device includes: a lighting unit configured to illuminate first illumination light and second illumination light, having different wavelengths, at different angles of incidence on a surface of a substrate moving along the transfer path; and a multichannel camera configured to generate an original image in which a dark field image based on scattered light according to the first illumination light and a bright field image based on direct-reflected light according to the second illumination light are integrated, wherein the optical metrology device on a transfer path of the substrate included in a substrate processing device.

According to an aspect of the present inventive concept, an optical metrology device includes: a lighting unit configured to illuminate first illumination light and second illumination light, having different wavelengths, at different angles of incidence onto a surface of a substrate moving along a transfer path; a multichannel camera configured to acquire scattered light of the first illumination light and direct-reflected light of the second illumination light with a multichannel camera, to generate an original image; and an inspection device configured to correct a shape of the original image to generate a corrected image, separate the corrected image according to a color channel, to generate a dark field image having illuminance information of the scattered light and a bright field image having illuminance information of the direct-reflected light, and analyze the dark field image and the bright field image to inspect a defect on the surface of the substrate.

According to an aspect of the present inventive concept, a substrate processing device includes a polisher configured to polish a surface of a substrate; a cleaner configured to clean the polished surface of the substrate; a transferor configured to transfer the substrate from the polisher to the cleaner; a loader configured to supply the substrate, before being processed, from a transfer container to the polisher, and to transfer the substrate, after being processed, from the cleaner to the transfer container; and an optical metrology device on a transfer path of the substrate between the cleaner and the transfer container, wherein the optical metrology device is configured to illuminate first illumination light and second illumination light, having different wavelengths, at different angles of incidence on the surface of the substrate moving along the transfer path, and to generate an original image in which a dark field image based on scattered light according to the first illumination light and a bright field image based on direct-reflected light according to the second illumination light are integrated.

According to an aspect of the present inventive concept, an optical inspection method includes illuminating first illumination light and second illumination light, having different wavelengths, at different angles of incidence onto a surface of a substrate moving along a transfer path; acquiring scattered light of the first illumination light and direct-reflected light of the second illumination light with a multichannel camera, to generate an original image; correcting a shape of the original image to generate a corrected image; separating the corrected image according to a color channel, to generate a dark field image having illuminance information of the scattered light and a bright field image having illuminance information of the direct-reflected light; and analyzing the dark field image and the bright field image to inspect a defect on the surface of the substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a view illustrating a substrate processing device according to some embodiments.

FIG. 2 is a flowchart illustrating a substrate processing method according to some embodiments.

FIGS. 3A and 3B are views illustrating defect types of a substrate.

FIGS. 4 and 5 are views illustrating an optical metrology device according to some embodiments.

FIG. 6 is a flowchart illustrating an optical inspection method according to some embodiments.

FIG. 7 is a view illustrating an optical path of an optical metrology device according to some embodiments.

FIG. 8 is a view illustrating an angle of incidence of illumination light of an optical metrology device according to some embodiments.

FIG. 9 is a graph illustrating illuminance according to a measurement angle of an optical metrology device and an angle of incidence of illumination light, according to some embodiments.

FIGS. 10A to 10F are views illustrating dark field images according to angles of incidence of illumination light according to some embodiments.

FIGS. 11A and 11B are views illustrating a method of generating a corrected image according to some embodiments.

FIG. 12 is a view schematically illustrating a method of inspecting a defect from a corrected image according to some embodiments.

FIG. 13 is a view illustrating a method of generating a feature map from an input image using a neural network operation.

FIGS. 14A to 14D are views illustrating an input image and a feature map generated from the input image.

FIG. 15 is a flowchart illustrating a method of learning a statistical model according to some embodiments.

FIG. 16 is a view illustrating a method of generating a statistical model according to some embodiments.

FIG. 17 is a flowchart illustrating a method of inspecting a defect according to some embodiments.

FIG. 18 is a view illustrating a Mahalanobis distance.

FIGS. 19A to 19D are views illustrating various input images, and inspection images and binary images, extracted based on the input images.

### DETAILED DESCRIPTION

Hereinafter, example embodiments of the present inventive concept will be described with reference to the accompanying drawings.

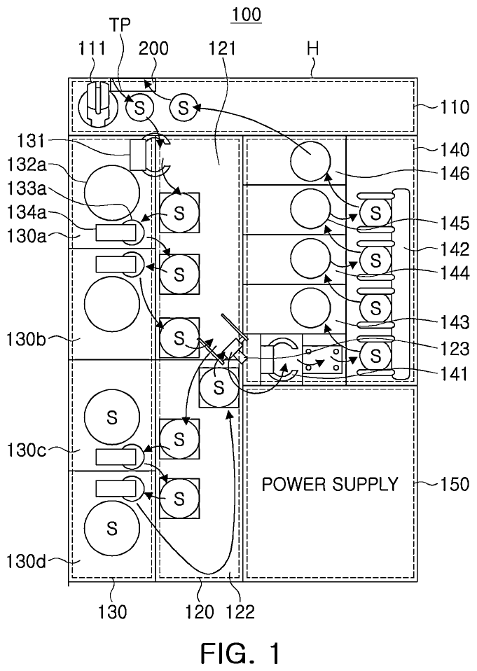

FIG. 1 is a view illustrating a substrate processing device according to some embodiments.

Referring to FIG. 1, a substrate processing device 100 may include a loader 110, a transferor 120, a polisher 130, a cleaner 140, and a power supplier 150, disposed in a housing H. The substrate processing device 100 may be used for a chemical-mechanical polishing (CMP) process for planarizing a surface of a substrate S during a process of manufacturing a semiconductor device. For example, the substrate S may be a wafer.

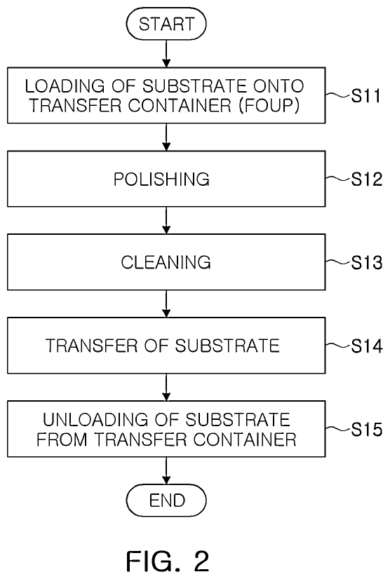

FIG. 2 is a flowchart illustrating a substrate processing method according to some embodiments. Referring to FIG. 2, a CMP process of a substrate processing device 100 may include operations S11 to S15. A transfer path TP of a substrate S according to the CMP process for the operations S11 to S15 may be illustrated in FIG. 1.

A loader 110 may provide the substrate S before the CMP process is performed to a polisher 130, and may receive the substrate S after the CMP process is completed from a cleaner 140. The loader 110 may include a transfer robot 111. In operation S11, when the substrate S is loaded into a transfer container (e.g., a front opening universal pod (FOUP)) outside a housing H, the transfer robot 111 may acquire the substrate S from the transfer container, and may load the same into the polisher 130.

The transferor 120 may transfer the substrate S along a predetermined transfer path such that the substrate S is polished and cleaned in a predetermined order. The transferor 120 may include linear transporters 121 and 122 and a swing transporter 123.

The polisher 130 may perform polishing of the substrate S. The polisher 130 may include a loading unit 131 and first to fourth polishing units 130a to 130d. The loading unit 131 may load the substrate S obtained from the transfer robot 111. The first to fourth polishing units 130a to 130d may have the same or different configurations. For example, the first polishing unit 130a may have a polishing pad 132a for fixing the substrate S, a polishing head 133a for polishing the substrate S, and a polishing arm 134a for controlling and holding a position of the polishing head 133a.

In operation S12, the substrate S loaded in the polisher 130 may be sequentially polished in the first to fourth polishing units 130a to 130d while moving along the linear transporters 121 and 122. In addition, the substrate S on which the polishing process is completed may be loaded into the cleaner 140 by the swing transporter 123.

The cleaner 140 may clean and dry the substrate S polished by the polisher 130. For example, the cleaner 140 may include a loading unit 141, transfer positions 142, brush units 143 and 144, a dual-fluid cleaning unit 145, and a drying unit 146.

The loading unit 141 may load the substrate S polished by the polisher 130. The substrate S may be sequentially transferred to the brush units 143 and 144, the dual-fluid cleaning unit 145, and the drying unit 146 along the transfer positions 142. The brush units 143 and 144 may brush a surface of the polished substrate S to remove a contaminant, the dual-fluid cleaning unit 145 may spray a fluid on the surface of the substrate S to remove a residual material, and the drying unit 146 may dry the surface of the substrate S.

In operation S13, the substrate S loaded in the loading unit 141 may sequentially move through the brush units 143 and 144, the dual-fluid cleaning unit 145, and the drying unit 146 along the transfer positions 142, and may be washed and dried.

In operation S14, the substrate S in which cleaning is completed may be received by the transfer robot 111, and may move along a predetermined transfer path of the loader 110 to be loaded into the transfer container. Then, in operation S15, the substrate S may be unloaded from the transfer container.

Various types of defects such as a scratch or discoloration may occur on the substrate S due to polishing or cleaning of the substrate S. A defect occurring in the substrate S may degrade electrical characteristics and performance of a semiconductor device formed on the substrate S, and as a result, yield of the semiconductor device may decrease.

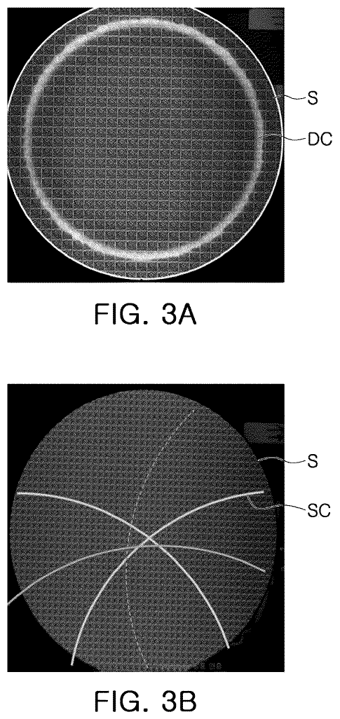

FIGS. 3A and 3B are views illustrating defect types of a substrate.

FIG. 3A is a view illustrating a discoloration defect occurring in a substrate S. A chemical substance used in an abrasive for polishing may discolor a surface of the substrate S by reflecting with a surface material of the substrate S. Referring to FIG. 3A, a discolored region DC is illustrated on a surface of a substrate S.

FIG. 3B illustrates a scratch defect occurring on a substrate S. A surface of the substrate S may be scratched by an abrasive particle used in an abrasive for CMP processing, and thus the scratch defect may occur. Referring to FIG. 3B, a scratch SC generated on a surface of a substrate S may be illustrated.

It is preferable that both the discoloration defect of FIG. 3A and the scratch defect of FIG. 3B are inspected for the substrate S after the CMP process. Comparing FIGS. 3A and 3B, the discolored region DC may have a relatively larger area than the scratch SC. Therefore, the discoloration defect of the substrate S may be detected by a bright field inspection that detects direct-reflected light from the substrate S.

Since a width of the scratch SC may be smaller than resolution of a camera for optical measurement, the scratch defect may be difficult to be detected by the bright field inspection. Since Rayleigh scattering or Mie scattering may occur in a scratch SC having a magnitude similar to a wavelength of light irradiated onto the substrate S, the scratch defect may be detected by a dark field inspection that detects scattered light from the substrate S.

In short, to inspect the substrate S for both the discoloration defect and the scratch defect, both the bright field inspection and the dark field inspection may be performed.

When the substrate S received from a substrate processing device 100 moves to a separate optical metrology device, and the optical metrology device needs to sequentially perform the bright field inspection and the dark field inspection, it may take a lot of time for inspecting the substrate S. When an inspection time period of the substrate S greatly increases, a production time period of the substrate S may increase and productivity may decrease.

According to some embodiments, an optical metrology device 200 may be included in the substrate processing device 100. Referring to FIG. 1, an optical metrology device 200 may be disposed on the transfer path TP of the substrate S in the loader 110. Specifically, the optical metrology device 200 may be disposed on a transfer path through which the substrate S is transferred from the cleaner 140 to the transfer container.

The optical metrology device 200 may simultaneously illuminate the surface of the substrate S being transferred along the transfer path W with first and second illumination lights having different wavelengths at different angles of incidence. For example, the first illumination light may be illumination light for the dark field inspection, and the second illumination light may be illumination light for the bright field inspection.

The optical metrology device 200 may collect reflected light reflected from the surface of the substrate S by the first and second illumination lights using an optical system, and may generate an original image based on the reflected light using a multichannel camera such as an RGB channel camera. Color channels of the original image may be separated to simultaneously acquire a dark field image by the first illumination light and a bright field image by the second illumination light.

According to some embodiments, since an optical system and a camera for acquiring the bright field image and the dark field image are integrated, a size of the optical metrology device 200 may be miniaturized, and the optical metrology device 200 may also be installed on the loader 110 having a limited space. Also, during transfer of the substrate S, the bright field image and the dark field image may be simultaneously acquired. Therefore, the bright field inspection and the dark field inspection may be performed without additional time in addition to time required to process the substrate S.

The present inventive concept is not limited to a case in which the optical metrology device 200 is included in the substrate processing device 100 for CMP processing. For example, the optical metrology device 200 may be included in a substrate processing device for etching, and may inspect a defect generated on the surface of the substrate S after etching.

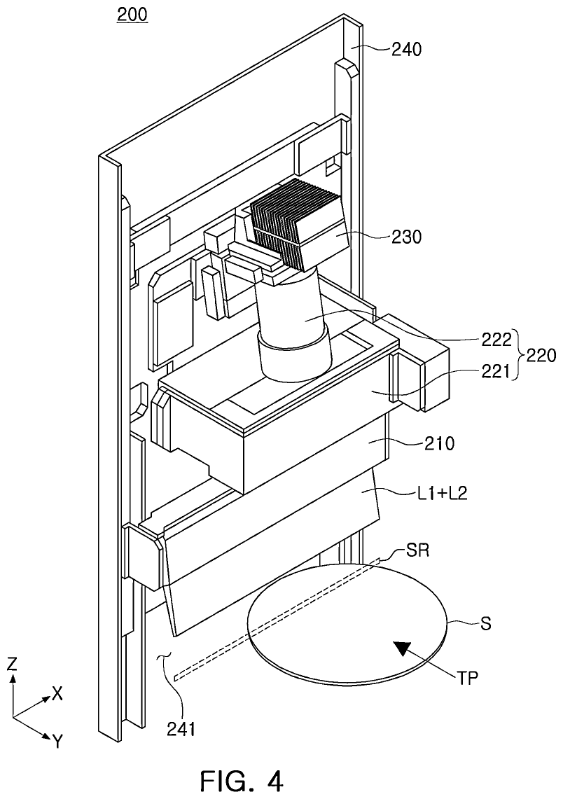

Hereinafter, an optical metrology device according to some embodiments will be described in detail with reference to FIGS. 4 to 19D.

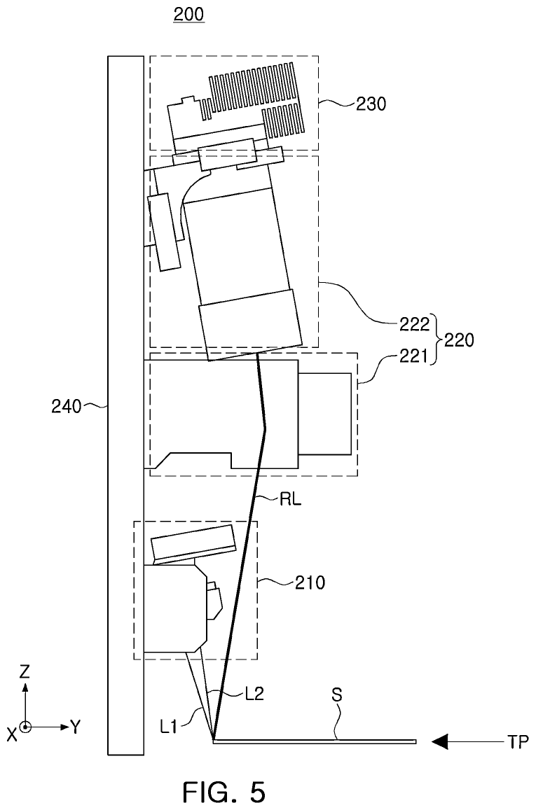

FIGS. 4 and 5 are views illustrating an optical metrology device according to some embodiments. FIG. 4 is a perspective view illustrating an optical metrology device 200 in an XYZ coordinate system, and FIG. 5 is a plan view illustrating an optical metrology device 200 in a Y-Z plane.

Referring to FIGS. 4 and 5 together, an optical metrology device 200 may include a lighting unit or lighting system 210, an optical system 220, a camera or camera unit or camera system 230 and a mount or mounting unit or mounting system 240. The optical metrology device 200 may be disposed on a transfer path TP of a substrate S.

The lighting unit 210 may illuminate the substrate S being transported along the transfer path TP with first illumination light and second illumination light, having different wavelengths. For example, the first illumination light may be red light (R), and the second illumination light may be green light (G) and blue light (B). The first illumination light may be illumination light for a dark field inspection, and the second illumination light may be illumination light for a bright field inspection, and may be illuminated on the substrate S at different angles of incidence.

The optical system 220 may collect reflected light RL from a surface of the substrate S by the first illumination light L1 and the second illumination light L2, and may transfer the collected light to the camera unit 230. The optical system 220 may include a mirror or mirror unit or mirror system 221 and a lens or lens unit or lens system 222 for increasing efficiency of a path of the reflected light and miniaturizing the optical system 220.

The reflected light may include direct-reflected light and scattered light. In reflected light by the first illumination light L1, scattered light may be more dominant than direct-reflected light, and in reflected light by the second illumination light L2, direct-reflected light may be more dominant than scattered light. The scattered light by the first illumination light L1 may include a red light (R) component, and the direct-reflected light by the second illumination light L2 may include a green light (G) component and a blue light (B) component.

The camera unit 230 may photograph the reflected light transmitted from the optical system 220 to generate an original image. The camera unit 230 may include a multichannel camera, for example, an RGB channel camera. The RGB channel camera may include red pixels configured to detect the red light, green pixels configured to detect the green light, and blue pixels configured to detect the blue light. The red pixels may sense the scattered light by the first illumination light L1, and the green pixels and the blue pixels may sense the direct-reflected light by the second illumination light L2.

The camera unit 230 may be implemented as a line scan camera to photograph the moving substrate S. In the line scan camera, the red pixels, the green pixels, and the blue pixels may be linearly arranged, respectively. The line scan camera may photograph a fixed scan region SR toward the moving substrate S multiple times, to obtain partial images of the substrate S, and may perform a scanning operation for reconstructing the partial images as a two-dimensional original image.

The scan region SR may be a linear region extending in a first direction X, and the linear region may intersect a second direction Y, which may be a transfer direction of the substrate S.

The original image generated by the camera unit 230 may be an image in which a dark field image by the scattered light of the first illumination light L1 and a bright field image by the direct-reflected light of the second illumination light L2 are integrated. The dark field image and the bright field image may be acquired by separating color channels of the original image.

Specifically, a corrected image may be divided into a red channel image, a green channel image, and a blue channel image. The red channel image may be determined as the dark field image, and the bright field image may be generated by combining the green channel image and the blue channel image. For example, the dark field image and the bright field image may be simultaneously acquired by a scanning operation of the camera unit 230.

According to some embodiments, the original image may be provided to an inspection device outside the optical metrology device 200, and the inspection device may divide the original image into a dark field image and a bright field image, may perform the dark field inspection based on the dark field image, and may perform the bright field inspection based on the bright field image. However, the present inventive concept is not limited thereto, and the inspection device may be included in the optical metrology device 200.

The mounting unit 240 may fix the lighting unit 210, the optical system 220, and the camera unit 230 to the substrate processing device 100. For example, the mounting unit 240 may be mounted on a wall above an exit of the substrate processing device 100, from which the substrate S is unloaded into the transfer container. The mounting unit 240 may include a passage 241 through which the substrate S comes in and out.

Hereinafter, an optical inspection method using the optical metrology device 200 will be described in detail.

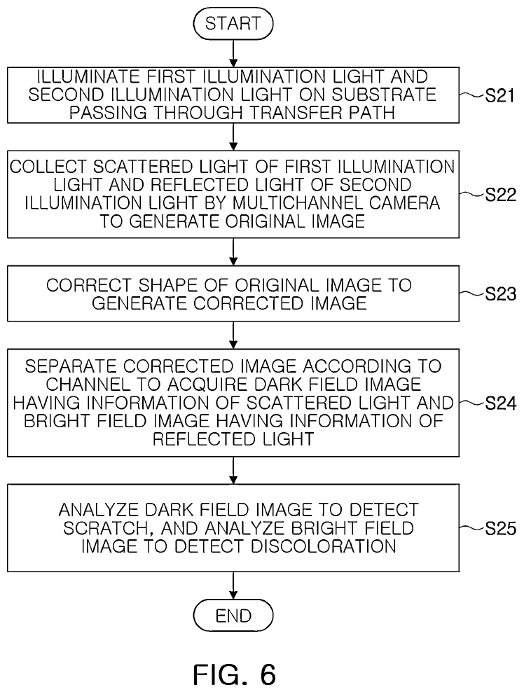

FIG. 6 is a flowchart illustrating an optical inspection method according to some embodiments.

In operation S21, first illumination light L1 and second illumination light L2 may be illuminated on a substrate S passing through a transfer path.

In operation S22, a multichannel camera may acquire scattered light by the first illumination light L1 and reflected light by the second illumination light L2 to generate an original image. When the original image is generated in a state in which the substrate S moves at non-uniform velocity on the transfer path, the original image may have a distorted shape, different from a shape of the substrate S.

In operation S23, a inspection device may correct a shape of the original image to generate a corrected image having the shape of the substrate S.

In operation S24, the inspection device may separate the corrected image according to a channel to acquire a dark field image having information of the scattered light and a bright field image having information of the reflected light.

In operation S25, the inspection device may analyze the dark field image to inspect a scratch defect, and may analyze the bright field image to inspect a discoloration defect.

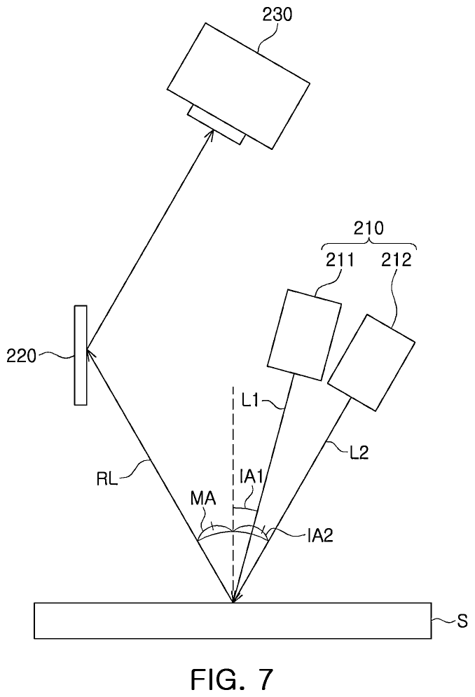

FIG. 7 is a view illustrating an optical path of an optical metrology device according to some embodiments. Specifically, FIG. 7 illustrates an optical path through which illumination light irradiated from a lighting unit 210 reaches a camera unit 230 via a substrate S and an optical system 220.

Referring to FIG. 7, the lighting unit 210 may include a first light or first lighting unit 211 irradiating a first lighting light L1 and a second light or second lighting unit 212 irradiating a second lighting light L2. A wavelength of the first illumination light L1 may be different from a wavelength of the second illumination light L2. For example, the first illumination light L1 may be red light, and the second illumination light L2 may include green light and blue light. Specifically, the first illumination light L1 may be light having a wavelength of 620 nm to 630 nm, and the second illumination light L2 may be light having a wavelength of 580 nm or less.

According to some embodiments, the first lighting unit 211 may generate the red light using red LED illumination, and the second lighting unit 212 may apply a short pass filter transmitting the green light and the blue light to white LED illumination, to generate the green light and the blue light. However, a method of generating the first illumination light L1 and the second illumination light L2 by the first lighting unit 211 and the second lighting unit 212 is not limited thereto.

An incidence angle of the first illumination light L1 may also be different from an incidence angle of the second illumination light L2. For example, the second illumination light L2 may be illuminated at a second angle of incidence IA2 having a difference of a critical angle or less than the critical angle from a measurement angle MA for a bright field inspection. Preferably, the second illumination light L2 may be illuminated at the second angle of incidence IA2, equal to the measurement angle MA. In this case, the measurement angle MA may refer to an angle of reflected light that may be observed by the camera unit 230, and the measurement angle MA may be determined according to arrangement of the camera unit 230 and arrangement of the optical system 220. When the second illumination light L2 is illuminated at the second angle of incidence IA2, equal to the measurement angle MA, the reflected light may be directly acquired from the camera unit 230, such that the bright field inspection may be effectively performed.

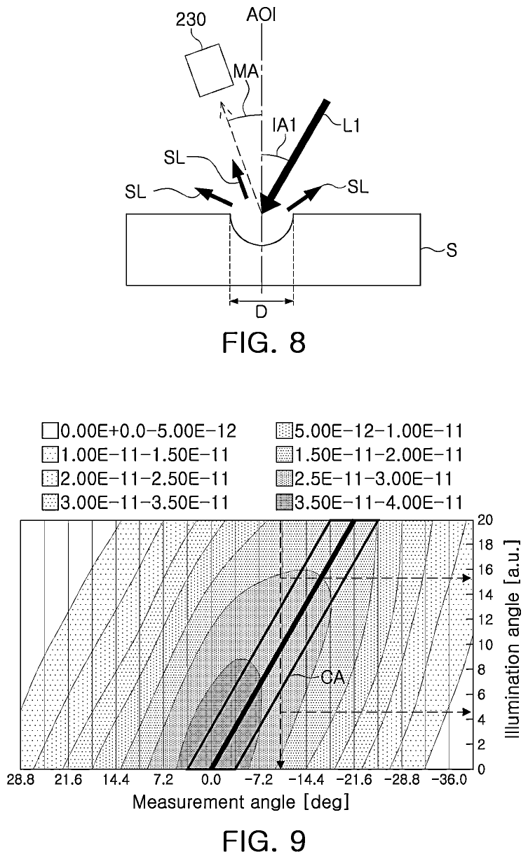

The first illumination light L1 may be illuminated at a first angle of incidence IA1 having a difference of more than the critical angle from the measurement angle MA for a dark field inspection. Hereinafter, the critical angle and the first angle of incidence IA1 will be described in detail with reference to FIGS. 8 to 10.

FIG. 8 is a view illustrating an angle of incidence of illumination light of an optical metrology device according to some embodiments.

FIG. 8 illustrates first illumination light L1 and scattered light SL on a surface of a substrate S having a scratch SC. The first illumination light L1 incident on the surface of the substrate S may be scattered in various directions by a defect such as the scratch SC. Among light rays scattered in various directions, a light ray scattered in a direction having an angle, equal to a measurement angle MA, may be incident to a camera unit 230.

Depending on the measurement angle MA and a first angle of incidence IA1 of the first illumination light L1, illuminance of the scattered light incident to the camera unit 230 may be changed. The measurement angle MA, the first angle of incidence IA1 of the first illumination light L1, and the second angle of incidence IA2 of the second illumination light L2 may be measured relative to a central or optical axis AOI (e.g., a vertical axis).

FIG. 9 is a graph illustrating illuminance according to a measurement angle of an optical metrology device and an angle of incidence of illumination light, according to some embodiments.

In the graph of FIG. 9, a horizontal axis denotes a measurement angle, and a vertical axis denotes an angle of incidence of illumination light. FIG. 9 illustrates illuminance of scattered light incident on a camera unit 230, according to a measurement angle and an angle of incidence, as a contour plot. Referring to FIG. 9, as a difference between the measurement angle and the angle of incidence decreases, illuminance of scattered light may increase, and as a difference between the measurement angle and the angle of incidence increases, illuminance of scattered light may decrease.

Light incident from a substrate S to the camera unit 230 by first illumination light L1 may include not only scattered light but also direct-reflected light by the first illumination light L1. The critical angle may be defined as an angle at which illuminance of the direct-reflected light and illuminance of the scattered light, collected in a direction of the measurement angle, are equal to each other. The illuminance of the direct-reflected light may significantly increase when the difference between the measurement angle and the angle of incidence is less than or equal to the critical angle, and may rapidly decrease when the difference between the measurement angle and the angle of incidence is more than the critical angle. FIG. 9 illustrates a region CA in which the difference between the measurement angle and the angle of incidence is less than or equal to the critical angle. In the example of FIG. 9, the critical angle may be 4 degrees.

When the light incident to the camera unit 230 includes the scattered light and the direct-reflected light, the direct-reflected light may act as noise in performing a dark field inspection. When the difference between the measurement angle and the angle of incidence is less than or equal to the critical angle, it may be difficult to acquire a normal dark field image because the illuminance of the direct-reflected light is greater than the illuminance of the scattered light.

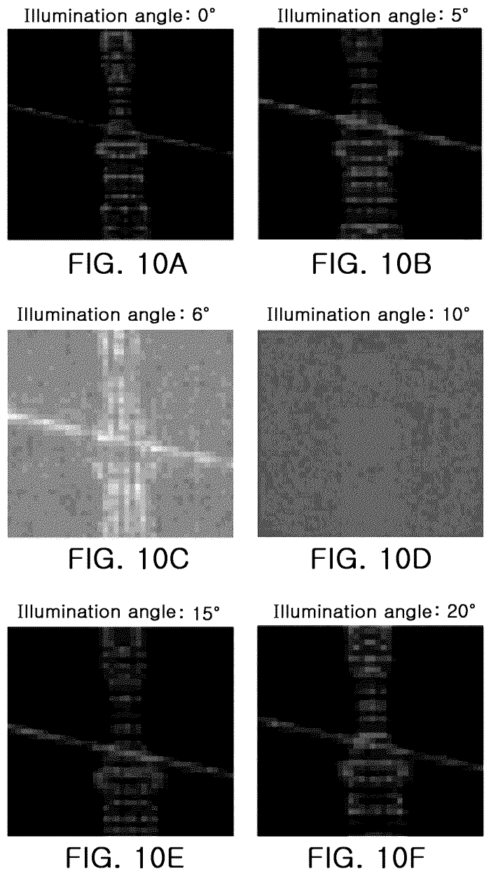

FIGS. 10A to 10F are views illustrating dark field images according to angles of incidence of illumination light according to some embodiments.

A measurement angle may be fixed according to arrangement of an optical system 220 and a camera unit 230. In examples of FIGS. 10A to 10F, the measurement angle may be fixed at 10 degrees.

Referring to FIGS. 10A to 10F, when angles of incidence of illumination light are 0 degree, 5 degrees, 15 degrees, or 20 degrees, e.g., a difference between the measurement angle and each of the angles of incidence is more than a critical angle, dark field images may appear distinctly. When angles of incidence of illumination light are 6 degrees or 10 degrees, e.g., a difference between the measurement angle and the angle of incidence is equal to or less than the critical angle, dark field images may appear blurry or hardly appear.

According to some embodiments, an angle of incidence of first illumination light L1 may be determined as an angle having a difference more than the critical angle from the measurement angle. Specifically, the angle of incidence of the first illumination light L1 may be determined as an angle at which a difference between illuminance of scattered light and illuminance of direct-reflected light is the largest in an angle range having a difference more than the critical angle from the measurement angle.

Hereinafter, a method of correcting a shape of an original image generated by acquiring scattered light from first illumination light L1 and reflected light from second illumination light L2 to generate a corrected image having a shape of a substrate S will be described.

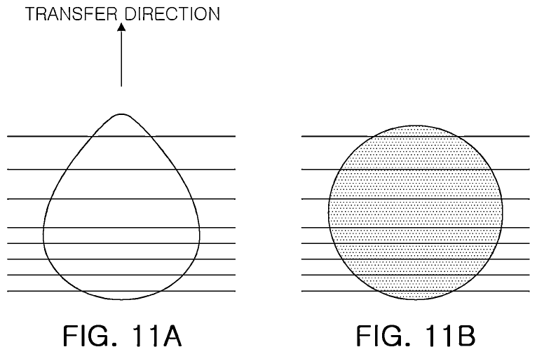

FIGS. 11A and 11B are views illustrating a method of generating a corrected image according to some embodiments. FIG. 11A illustrates an original image before correction, and FIG. 11B illustrates a corrected image.

Referring to FIG. 11A, an original image may have a shape, different from a shape of a substrate S. Specifically, a camera unit 230 may be a line scan camera, and may continuously photograph a fixed scan region, and the substrate S may be scanned in a two-dimensional shape while passing through the scan region. In FIG. 11A, an original image scanned in a two-dimensional shape and a region scanned at several viewpoints having constant time intervals on the original image may be displayed as lines.

The substrate S may not always move at a constant speed in a transfer path, and the original image may have a distorted shape in a section in which the substrate S does not move at a constant speed. For example, when the substrate S having a circular shape is accelerated, the original image may not have a circular shape, but may have a shape elongated in a transfer direction.

The original image of FIG. 11A may be corrected to have a shape, equal to the shape of the substrate S, in a similar manner to a corrected image illustrated in FIG. 11B. For example, a corrected image having a circular shape may be generated by detecting a degree of distortion of the original image based on the shape of the original image and adjusting coordinate values corresponding to the transfer direction of the original image. On the corrected image of FIG. 11B, a region corresponding to a region scanned in the original image of FIG. 11A may be marked with a line.

According to some embodiments, among pixel values of red pixels, pixel values of green pixels, and pixel values of blue pixels constituting the original image, at least the pixel values of the green pixels and the pixel values of the blue pixels may be used to detect the shape of the original image. Since the green pixels and the blue pixels may collect direct-reflected light for bright field inspection, the pixel values of the green pixels and the pixel values of the blue pixels may be greater than the pixel values of the red pixels, respectively. Therefore, the shape of the original image may be more easily detected when the pixel values of the green pixels and the pixel values of the blue pixels are used.

It may be difficult to detect a defect, particularly a scratch, using the corrected image as it is. For example, even when the corrected image is corrected to have the shape of the substrate S, the corrected image may have slightly distorted patterns, as compared to an image obtained by photographing a still substrate S.

According to some embodiments, characteristics of the corrected image may be extracted by performing a neural network operation on the corrected image, and a defect may be inspected based on the characteristics. Thus, a defect may be effectively inspected even when the corrected image has somewhat distorted patterns.

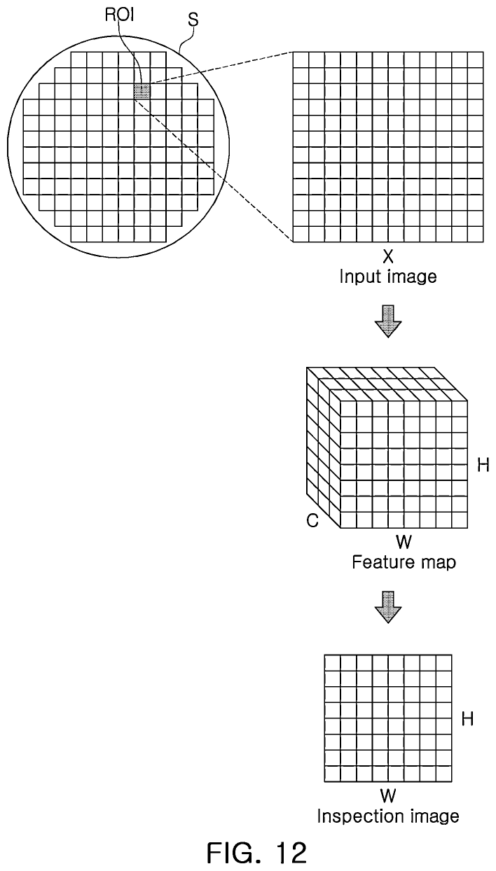

Hereinafter, a method of inspecting a defect using neural network operation by an inspection device will be described in detail with reference to FIGS. 12 to 19D.

FIG. 12 is a view schematically illustrating a method of inspecting a defect from a corrected image according to some embodiments.

According to some embodiments, to detect a scratch from a corrected image representing a surface of a substrate S, a dark field image may be extracted. In addition, to apply a neural network operation to the dark field image, the corrected image may be divided into a plurality of input images. When the neural network operation is applied by dividing the dark field image into the plurality of input images, a degree of complexity of the neural network operation may be reduced.

A plurality of regions of interest ROI may be set on the surface of the substrate S. For example, the substrate S may include a plurality of chip regions in which semiconductor chips are formed, and each of the plurality of chip regions may be set as a region of interest ROI. However, the present inventive concept is not limited thereto, and the region of interest ROI may be set over a plurality of chip regions, or may be set in a region smaller than a chip region. The dark field image may be divided into a plurality of input images based on regions of interest ROI.

An input image may include a plurality of pixels. A position of each of the pixels may be expressed as coordinate values (X, Y), and each of the coordinate values may correspond to different portions of the region of interest ROI. A value of each of the pixels may represent illuminance of reflected light from different portions of the region of interest ROI. The input image may have information about patterns formed in the region of interest ROI and information about defects.

Each of the input images may be used as an input for a neural network operation, and a feature map corresponding to the input image may be output as an output of the neural network operation. In the feature map output according to the neural network operation, the information about defects may be emphasized, compared to an original input image.

According to some embodiments, the feature map may be three-dimensional data having a width W, a height H, and a channel C. Coordinate values of the width W and height H of the feature map may correspond to each portion of the region of interest ROI. Hereinafter, a position specified by the coordinate values of the width W and height H of the feature map may be referred to as a planar position of the feature map.

In general, the feature map may have a plurality of channels C emphasizing different information in an input image. Each of the planar positions of the feature map may have a feature vector including a plurality of features.

In general, a size of a plane specified by the width W and height H of the feature map may be smaller than a size of the input image. For example, both the feature map and the input image may correspond to the region of interest ROI, but resolution of the feature map may be lower than resolution of the input image.

The feature map may be applied to a statistical model, to generate an inspection image representing a statistical distance of each portion of the region of interest ROI. The inspection image may be two-dimensional data having a width W and a height H, and coordinate values of the width W and the height H may correspond to each portion of the region of interest ROI.

The statistical distance may be a numerical value indicating how unlikely a certain value is to occur statistically. According to some embodiments, a planar position having a statistical distance greater than or equal to a threshold value in the inspection image may be determined as a position in which a defect is present.

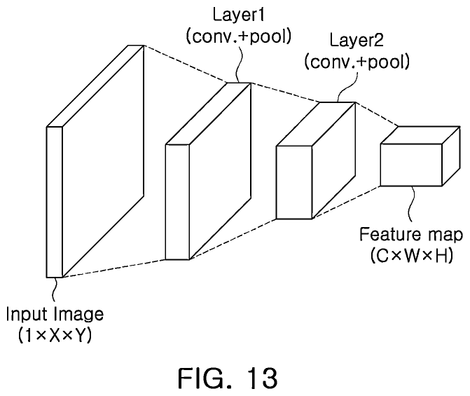

Hereinafter, a method of inspecting a defect from a corrected image according to some embodiments will be described in detail with reference to FIGS. 13 to 18.

FIG. 13 is a view illustrating a method of generating a feature map from an input image using a neural network operation. Specifically, FIG. 13 illustrates a method of generating a feature map from an input image using a convolutional neural network (CNN).

Referring to FIG. 13, a CNN may include a plurality of layers including Layer1 and Layer2. An input image (1×X×Y) may be input to a first layer Layer1, and an output of one layer may be an input of the next layer. And, a feature map (C×W×H) may be output from the last layer Layer2.

Each of the plurality of layers may include a convolution layer, and may optionally further include a pooling layer. In the convolution layer, the feature map may be generated by performing a convolution operation on an input image of the convolution layer and each of one or more filters.

A plurality of filters may be used in one convolution layer to extract various characteristics from the input image. A filter may refer to a weight matrix for emphasizing a characteristic in an input image.

For example, in the present inventive concept, to extract a scratch, a Sobel filter, a Prewitt filter, or the like for detecting an edge of an image may be used, and a filter for histogram of oriented gradients (HOG) feature extraction may be used.

The pooling layer may reduce sizes of the feature maps by downscaling output feature maps. For example, when max pooling is performed in the pooling layer, the feature map may be downscaled by preserving only a maximum value in each pooling window of the feature map and deleting remaining values.

According to some embodiments, even when an input image has a distorted pattern, characteristics may be extracted from an input image using a CNN. And, a defect may be inspected based on the characteristics.

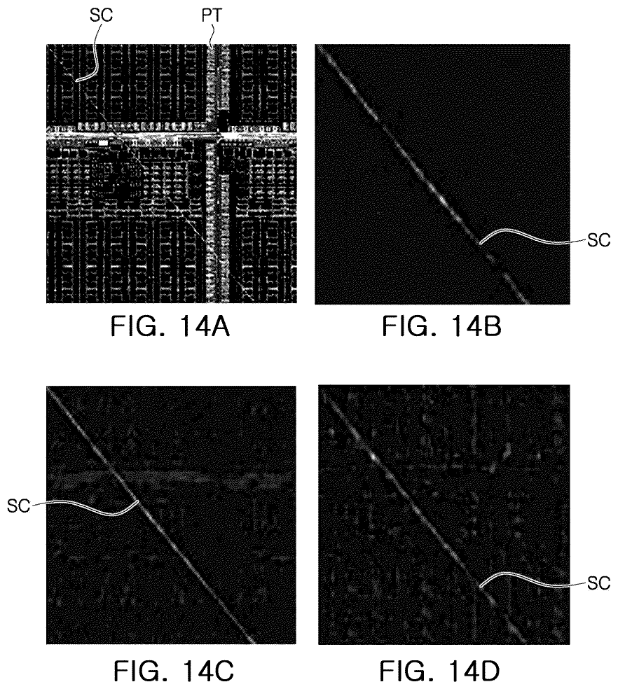

FIGS. 14A to 14D are views illustrating an input image and a feature map generated from the input image.

FIG. 14A illustrates an input image, and FIGS. 14B to 14D illustrate two-dimensional images constituting feature maps generated by applying a CNN to the input image.

Referring to the input image of FIG. 14A, patterns PT and a scratch SC in a region of interest ROI may have a similar brightness, and a background portion without patterns or a scratch may be displayed relatively darkly. The patterns PT and the scratch SC in an input image may have similar pixel values, and it may be difficult to identify the scratch SC in the input image.

Two-dimensional images in FIGS. 14B to 14D illustrate feature values in different channels corresponding to a region of interest ROI. Referring to FIGS. 14B to 14D, in each two-dimensional image constituting a feature map, a portion having a scratch SC in a region of interest ROI may be displayed relatively brightly, and patterns and a background portion may be displayed relatively darkly. For example, in the feature map, the portion having the scratch may be emphasized. Therefore, the portion having the scratch in the region of interest ROI may be easily identified by using the feature map.

According to some embodiments, a statistical model for characteristics of a surface of a substrate S may be learned by using feature maps generated using input images for various patterns of the substrate S. In addition, it may be inspected whether the substrate S is defective by applying the statistical model to a feature map of an input image of the substrate S to be inspected for defects.

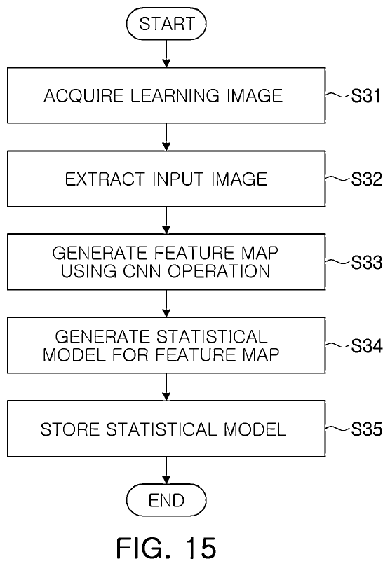

FIG. 15 is a flowchart illustrating a method of learning a statistical model according to some embodiments.

In operation S31, learning images may be acquired. For example, when an inspection to be performed using a neural network model is a dark field inspection, the learning images may include dark field images obtained from a plurality of substrates S having various patterns on surfaces thereof.

According to some embodiments, to acquire a characteristic of a surface of a substrate S without a defect, the learning images may be selected from images obtained from substrates not including a defect.

In operation S32, an input image may be extracted from the learning images. For example, at least a portion of a plurality of semiconductor chip regions included in the substrate S may be selected as regions of interest, and input images corresponding to the regions of interest may be extracted. Input images for statistical model learning may be referred to as input images for learning to distinguish them from input images for optical inspection.

In operation S33, feature maps may be generated by performing a CNN operation on each of the input images for learning. A method of generating the feature maps has been described with reference to FIG. 13. Feature maps for statistical model learning may be referred to as feature maps for learning to distinguish them from feature maps for optical inspection.

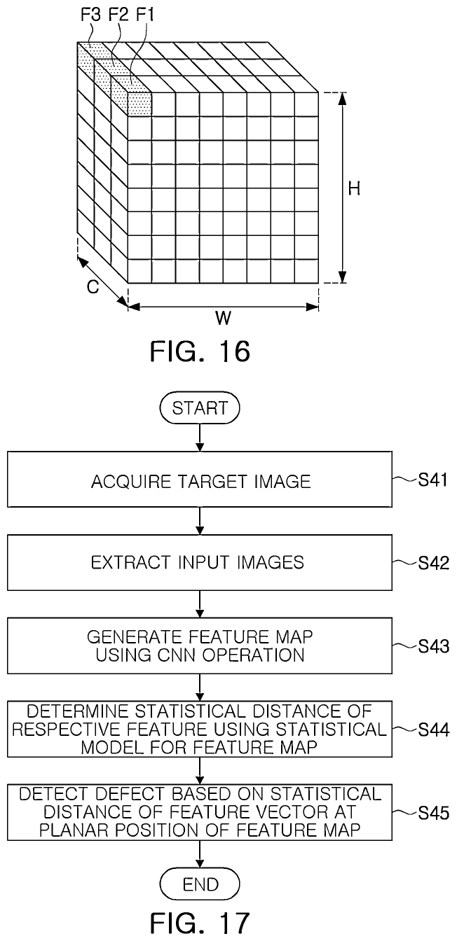

In operation S34, a statistical model for the regions of interest may be generated. For example, the statistical model for the regions of interest may include an average value of each feature in the feature maps for learning, and a covariance between two different features. A method of generating a statistical model for each feature will be described later with reference to FIG. 16.

In operation S35, the statistical model may be stored for defect inspection. For example, the statistical model may be stored in an inspection device.

FIG. 16 is a view illustrating a method of generating a statistical model according to some embodiments.

Referring to FIG. 16, a feature map generated from an input image is illustrated. As described with reference to FIG. 12, the feature map may include three-dimensional data including a width W, a height H, and number of channels C.

A plane including the width W and the height H in the feature map may correspond to the input image. The plane may have resolution, lower than resolution of the input image, and a characteristic of the input image may be emphasized. Also, in the feature map, different characteristics of the input image may be emphasized for each channel.

To generate a statistical model, a plurality of feature maps for learning may be generated. For example, when a CNN is applied to N input images, N feature maps may be generated, as illustrated in FIG. 16.

According to some embodiments, an average vector of each feature vector corresponding to each planar position and a covariance matrix of each feature vector may be determined, based on the plurality of feature maps for learning.

For example, a feature vector may include feature values for each channel at a planar position specified by horizontal and vertical positions of the feature map. The average vector of the feature vectors may be determined by averaging feature values for each channel in the feature maps for learning.

And, a covariance of feature vectors corresponding to a certain planar position may be determined as follows. In FIG. 16, features F1, F2, and F3 for each channel corresponding to a planar position (1, 1) may be shaded. The features F1, F2, and F3 for each channel may constitute a feature vector.

A covariance matrix Cov(1, 1) for the planar position (1, 1) may be determined as illustrated in the following Equation 1, based on the features F1, F2, F3 corresponding to the planar position (1, 1):

$$Cov ( 1 , 1 ) = ( \begin{matrix}Var ( F 1 ) & Cov ( F 1 , F 2 ) & Cov ( F 1 , F 3 ) \\ Cov ( F 2 , F 1 ) & Var ( F 2 ) & Cov ( F 2 , F 3 ) \\ Cov ( F 3 , F 1 ) & Cov ( F 3 , F 2 ) & Var ( F 3 )\end{matrix} ) \qquad [ Equation 1 ]$$

In Equation 1, variances Var(F1), Var(F2), and Var(F3) may be determined as variances for features F1, F2, and F3 in a plurality of feature maps, respectively. Also, covariances may be determined according to a correlation between two features in each of the plurality of feature maps. For example, Cov(F1, F2) may be determined, based on a correlation between features F1 and F2 in each of the plurality of feature maps.

Similarly, a covariance matrix of a feature vector corresponding to a certain planar position of a feature map may be determined based on a covariance of features corresponding to each planar position.

An inspection image may be generated by applying a statistical model including an average value and a covariance matrix to a feature map generated based on a target image to be inspected for defects. And, a defect inspection may be performed based on the inspection image.

FIG. 17 is a flowchart illustrating a method of inspecting a defect according to some embodiments.

In operation S41, an image of a substrate on which a defect inspection is to be performed, for example, a target image, may be acquired. For example, when an inspection to be performed using a neural network model is a dark field inspection, an inspection image may be a dark field image generated by first illumination light L1.

In operation S42, input images may be extracted from the inspection image. For example, a plurality of regions of interest may be set on the target substrate, and input images respectively corresponding to the regions of interest may be extracted from the dark field image.

In operation S43, a feature map may be generated by performing a CNN operation on each of the input images. Feature maps may be generated for all input images such that an entire region of the target substrate may be inspected for defects. A method of generating a feature map by performing a CNN operation on an input image has been described with reference to FIG. 13.

In operation S44, a statistical distance of feature vectors respectively corresponding to planar positions of the feature map may be determined using the statistical model of the feature map. According to some embodiments, the statistical distance may be determined as a Mahalanobis distance. The Mahalanobis distance may be a numerical value indicating how many times a value of a variable differs from a mean value of the variable and normal distribution.

According to some embodiments, based on an average value of each feature of a feature vector at a planar position of a feature map and a covariance matrix of the feature vector at the planar position, a Mahalanobis distance of a feature vector at the planar position may be determined. The Mahalanobis distance of the planar position may represent as a numerical value how difficult it is to statistically generate feature values of a feature vector of the planar position in a feature map.

In operation S45, an inspection image may be constructed based on a statistical distance of a feature vector corresponding to a planar position, and a defect in the region of interest may be detected based on the inspection image.

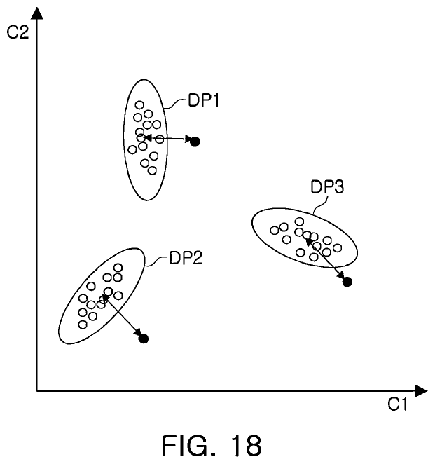

FIG. 18 is a view illustrating a Mahalanobis distance.

As described above, a planar position of a feature map may correspond to a feature vector including features for each channel. A graph of FIG. 18 may have a first channel C1 axis and a second channel C2 axis, among a plurality of channels included in the feature map. In the above graph, feature vectors are illustrated according to a first channel C1 component and a second channel C2 component of the feature vectors, corresponding to planar positions.

Feature vectors of planar positions may form constant distribution. In the graph of FIG. 18, first distribution DP1 of feature vectors corresponding to a first position, second distribution DP2 of feature vectors corresponding to a second position, and third distribution DP3 of feature vectors corresponding to a third position are illustrated.

As a feature vector of a certain planar position is further away from distribution of the feature vector, feature values included in the feature vector may be values that may be statistically unlikely to occur. A Mahalanobis distance may be calculated to determine how unlikely any feature vector is statistically.

In a feature map generated from a target image, a Mahalanobis distance for a feature vector \vec{x} of a certain planar position may be determined according to Equation 2 below:

$$d ( \vec{x} ) = \sqrt{( \vec{x} - \vec{u} ) {\sum }^{- 1} {( \vec{x} - \vec{u} )}^{T}} \qquad [ Equation 2 ]$$

In Equation 2, \vec{u} may indicate an average vector of a feature vector \vec{x}, and Σ may indicate a covariance matrix of the feature vector \vec{x}. In the example of FIG. 16, the feature vector \vec{x} of the planar position (1, 1) may include the features F1, F2, and F3.

Based on a Mahalanobis distance for a feature vector of planar positions of a feature map, an inspection image may be generated. The inspection image may have a width W and a height H, equal to those of the feature map, and planar positions of the inspection image may include a Mahalanobis distance of a feature vector corresponding to the planar positions of the feature map, respectively.

The inspection image may correspond to a region of interest ROI. According to some embodiments, it may be determined that there is a defect in a planar position having a value, greater than or equal to a predetermined size in the inspection image.

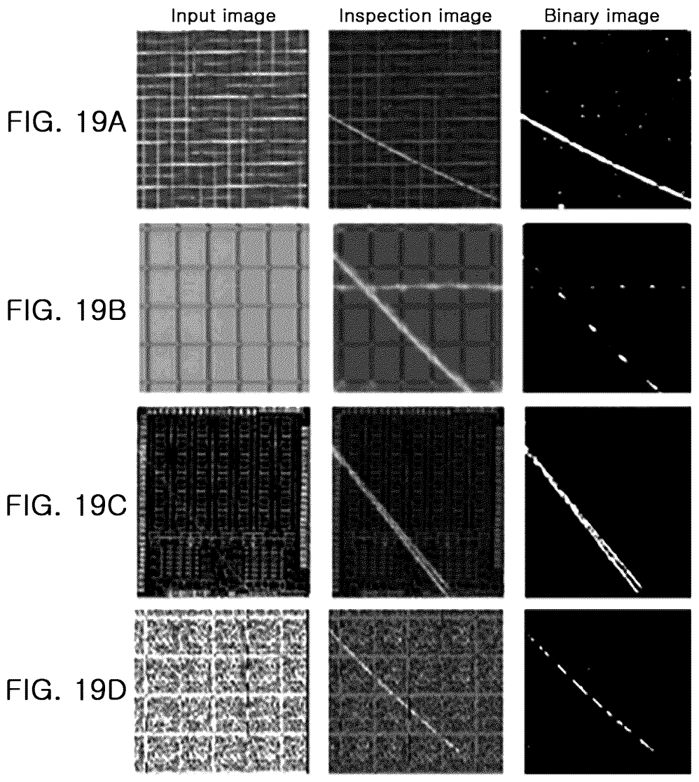

FIGS. 19A to 19D are views illustrating various input images, and inspection images and binary images, extracted based on the input images.

FIGS. 19A to 19D illustrate an inspection image generated by applying a statistical model to an input image having various patterns, and a binary image obtained by binarizing the inspection image based on a predetermined threshold.

Referring to FIG. 19A, a portion having a pattern and a portion having a scratch, in an input image, may have similar illuminance, and the portion having a scratch may not appear clearly, as compared to the portion having a pattern.

In an inspection image generated by applying a statistical model, a scratch that may be statistically unlikely to occur may be emphasized, as compared to patterns that may occur statistically frequently.

In a binary image generated based on the inspection image, a position of a plane having a feature vector having a Mahalanobis distance, greater than or equal to a threshold value, and a position of a plane having a feature vector having a Mahalanobis distance, less than the threshold value, in the inspection image, may be displayed as different values. In the example of FIG. 19A, a white portion of the binary image may indicate a scratch.

Learning images generated from substrates S having various patterns may be used to generate a statistical model. Therefore, inspection images in which scratches are emphasized may be generated in input images of FIGS. 19B to 19D having patterns, different from those of the input image of FIG. 19A. For example, a statistical model according to some embodiments may be applied to detect a defect of a substrate S having various patterns.

An optical metrology device according to some embodiments may generate an original image in which a dark field image and a bright field image are integrated during transfer of a substrate. Thus, a bright field inspection and a dark field inspection may be performed without requiring an additional time period for generating the original image. In addition, productivity degradation due to time required for the bright field inspection and the dark field inspection may be prevented.

A substrate processing device according to some embodiments may include an optical metrology device. An optical metrology device for a bright field inspection and an optical metrology device for a dark field inspection may be integrated to space-efficiently arrange the optical metrology devices on a transfer path of the substrate processing device.

An optical inspection method according to some embodiments may correct distortion of a shape of a multichannel image generated during transfer of a substrate, and may thus detect a defect in the substrate using features extracted from the corrected image using a neural network operation.

Ultimately, since substrates processed by a substrate processing device may be thoroughly inspected without reducing productivity, and substrates having various defects may be removed in advance, electrical characteristics and yield of semiconductor devices produced by the substrates may also be improved.

An optical metrology device according to some embodiments may generate an original image in which a dark field image and a bright field image are integrated during transfer of a substrate. Thus, a bright field inspection and a dark field inspection may be performed without requiring an additional time period for generating the original image.

A substrate processing device according to some embodiments may include an optical metrology device. An optical metrology device for a bright field inspection and an optical metrology device for a dark field inspection may be integrated to space-efficiently arrange the optical metrology devices on a transfer path of the substrate processing device.

An optical inspection method according to some embodiments may correct distortion of a shape of a multichannel image generated during transfer of a substrate, and may thus detect a defect in the substrate using features extracted from the corrected image using a neural network operation.

Problems to be solved by the present inventive concept are not limited to the problems mentioned above, and other problems not mentioned will be clearly understood by those skilled in the art from the description above.

While example embodiments have been illustrated and described above, it will be apparent to those skilled in the art that modifications and variations could be made without departing from the scope of the present inventive concept as defined by the appended claims.

What is claimed is:

1. An optical metrology device comprising:
a lighting unit configured to simultaneously illuminate first illumination light at a first angle of incidence having a difference more than a critical angle from a measurement angle, and second illumination light having a wavelength, different from a wavelength of the first illumination light, at a second angle of incidence having a difference equal to or less than the critical angle from the measurement angle, onto a surface of a substrate;
an optical system configured to collect reflected light from the surface of the substrate according to the first illumination light and the second illumination light; and
a multichannel camera configured to generate an original image in which a dark field image and a bright field image of the surface of the substrate are integrated, based on the reflected light collected by the optical system.

2. The optical metrology device of claim 1, wherein the first illumination light is red light, and the second illumination light comprises green light and blue light, and
the multichannel camera comprises red pixels, green pixels, and blue pixels, and is configured to generate the dark field image having a scattered light component according to the first illumination light using the red pixels, and to generate the bright field image having a direct-reflected light component according to the second illumination light using the green pixels and the blue pixels.

3. The optical metrology device of claim 1, wherein the wavelength of the first illumination light is 620 nm to 630 nm, and the wavelength of the second illumination light is 580 nm or less.

4. The optical metrology device of claim 1, wherein the lighting unit comprises:
a first lighting unit configured to use red LED illumination to generate red light, and
a second lighting unit configured to apply a short pass filter to white LED illumination to generate green light and blue light.

5. The optical metrology device of claim 1, wherein the reflected light comprises scattered light and direct-reflected light, and
the critical angle is determined by an angle at which illuminance of the scattered light collected in a direction of the measurement angle is equal to illuminance of the direct-reflected light.

6. The optical metrology device of claim 1, wherein the critical angle is 4 degrees.

7. The optical metrology device of claim 1, wherein the second angle of incidence is equal to the measurement angle.

8. An optical metrology device comprising:
a lighting unit configured to illuminate first illumination light and second illumination light, having different wavelengths, at different angles of incidence on a surface of a substrate moving along the transfer path; and
a multichannel camera configured to generate an original image in which a dark field image based on scattered light according to the first illumination light and a bright field image based on direct-reflected light according to the second illumination light are integrated,
wherein the optical metrology device on a transfer path of the substrate included in a substrate processing device.

9. The optical metrology device of claim 8, wherein the multichannel camera includes a line scan camera, and
the line scan camera is configured to photograph a fixed region facing the moving substrate a plurality of times, to acquire partial images of the surface of the substrate, and to perform a scan operation to reconstruct the partial images into a two-dimensional original image.

10. The optical metrology device of claim 9, wherein the fixed region extends in a direction perpendicular to a transfer direction of the substrate.

11. The optical metrology device of claim 10, wherein the first illumination light is red light, and the second illumination light comprises green light and blue light, and
the line scan camera comprises red pixels, green pixels, and blue pixels, respectively arranged in a linear manner, wherein the red pixels generate the dark field image, and the green pixels and the blue pixels generate the bright field image.

12. The optical metrology device of claim 8, wherein the optical metrology device is mounted on a surface or wall above an exit of the substrate processing device, from which the substrate is carried out to a transfer container of the substrate processing device.

13. An optical metrology device comprising:
a lighting unit configured to illuminate first illumination light and second illumination light, having different wavelengths, at different angles of incidence onto a surface of a substrate moving along a transfer path;
a multichannel camera configured to acquire scattered light of the first illumination light and direct-reflected light of the second illumination light with a multichannel camera, to generate an original image; and
an inspection device configured to correct a shape of the original image to generate a corrected image, separate the corrected image according to a color channel, to generate a dark field image having illuminance information of the scattered light and a bright field image having illuminance information of the direct-reflected light, and analyze the dark field image and the bright field image to inspect a defect on the surface of the substrate.

14. The optical metrology device of claim 13, wherein the inspection device corrects a shape of the original image to generate a corrected image by:
sensing a degree of distortion of the original image based on the shape of the original image, and
adjusting coordinate values corresponding to a transfer direction of the original image, to generate a corrected image having a shape of the substrate.

15. The optical metrology device of claim 13, wherein the inspection device separates the corrected image according to a color channel, to generate a dark field image having illuminance information of the scattered light and a bright field image having illuminance information of the direct-reflected light by:
separating the corrected image into a red channel image, a green channel image, and a blue channel image,
determining the red channel image as the dark field image, and
merging the green channel image and the blue channel image to generate the bright field image.

16. The optical metrology device of claim 13, wherein the inspection device analyzes the dark field image and the bright field image to inspect a defect on the surface of the substrate by:
detecting discoloration from the bright field image, and
detecting a scratch from the dark field image.

17. The optical metrology device of claim 16, wherein the inspection device detects a scratch from the dark field image by:
dividing the dark field image into a plurality of input images,
generating a feature map of each of the plurality of input images using a convolutional neural network (CNN) operation,
calculating a statistical distance of feature vectors including features per channel respectively corresponding to planar positions of the feature map, by applying the feature map to a statistical model,
generating an inspection image having information on the statistical distance of the feature vectors at each of the planar positions, and
detecting a planar position in which a statistical distance of a feature vector is equal to or greater than a threshold value in the inspection image as a position in which a scratch is present.

18. The optical metrology device of claim 17, wherein the inspection device calculates a statistical distance of feature vectors by:
calculating a Mahalanobis distance based on a feature vector corresponding to the planar position, an average vector corresponding to the planar position in the statistical model, and a covariance matrix.

19. The optical metrology device of claim 17, wherein the inspection device further configured to:
acquire dark field images obtained from a plurality of substrates having different patterns as learning images,
extract input images for learning from the learning images,
perform a CNN operation on each of the input images for learning to generate feature maps for learning, and
generate average vectors of feature vectors corresponding to planar positions in the feature maps for learning and a covariance matrix of the feature vectors, as the statistical model.

20. The optical metrology device of claim 19, wherein the learning images comprise images acquired from substrates that do not contain a defect.
